(19) United States
(12) Patent Application Publication
(10) Pub. No.: US 2022/0013469 A1
(43) Pub. Date: Jan. 13, 2022

(54) SEMICONDUCTOR DEVICE AND METHOD FOR FABRICATING THE SAME

(71) Applicant: SK hynix Inc., Icheon-si Gyeonggi-do (KR)

(72) Inventor: Hyun Chul SEO, Icheon-si Gyeonggi-do (KR)

(73) Assignee: SK hynix Inc., Icheon-si Gyeonggi-do (KR)

(21) Appl. No.: 17/018,608

(22) Filed: Sep. 11, 2020

(30) Foreign Application Priority Data
Jul. 8, 2020 (KR) 10-2020-0083996

(51) Int. Cl. H01L 23/544; H01L 23/00; H01L 23/538

(52) U.S. Cl. CPC H01L 23/544; H01L 23/5385; H01L 23/5386; H01L 24/14

(57) ABSTRACT

A semiconductor device includes: a semiconductor wafer with a chip region and an edge region and with an identification mark formed on one surface of the semiconductor wafer in the edge region; conductive connectors formed on the one surface of the semiconductor wafer in the chip region; and dummy conductive connectors formed on the one surface of the semiconductor wafer in the edge region, wherein the dummy conductive connectors do not overlap with the identification mark.

### CROSS-REFERENCE TO RELATED APPLICATION

This application claims priority under 35 U.S.C. § 119 to Korean Patent Application No. 10-2020-0083996 filed on Jul. 8, 2020, which is incorporated herein by reference in its entirety.

### BACKGROUND

### 1. Technical Field

This patent document relates to a semiconductor technology, and more particularly, to a semiconductor device with a semiconductor wafer, and a method for fabricating the same.

### 2. Related Art

A semiconductor wafer may have a plurality of chip regions in that semiconductor devices are integrated. The plurality of chip regions may be separated into a plurality of semiconductor chips by dicing.

While the semiconductor wafer has a circular shape or a shape similar thereto, the chip region has a rectangular shape so that the semiconductor wafer has a residual region outside of the chip regions. This residual region may be used for a variety of purposes. As an example, an identification mark with identification information of the semiconductor wafer may be formed in this residual region.

### SUMMARY

In an embodiment, a semiconductor device may include: a semiconductor wafer with a chip region and an edge region and with an identification mark formed on one surface of the semiconductor wafer in the edge region; conductive connectors formed on the one surface of the semiconductor wafer in the chip region; and dummy conductive connectors formed on the one surface of the semiconductor wafer in the edge region, wherein the dummy conductive connectors do not overlap with the identification mark.

In an embodiment, a method for fabricating a semiconductor device, may include: providing a semiconductor wafer with a chip region and an edge region, the semiconductor wafer including an identification mark that is formed on one surface of the semiconductor wafer in the edge region; forming a photoresist pattern with a plurality of openings in the chip region and the edge region over the one surface of the semiconductor wafer; forming conductive connectors in the plurality of openings of the chip region and forming dummy conductive connectors in the plurality of openings of the edge region; and removing the photoresist pattern, wherein the openings of the edge region do not overlap with the identification mark.

### BRIEF DESCRIPTION OF THE DRAWINGS

FIG. 1 is a plan view, illustrating a semiconductor wafer, according to an embodiment of the present disclosure.

FIGS. 2 to 4 are plan views, illustrating semiconductor devices in accordance with various embodiments of the present disclosure.

FIG. 5A is a view, illustrating heights of conductive connectors that are formed in a chip region in a case of the embodiment of FIG. 4.

FIG. 5B is a view, illustrating heights of conductive connectors that are formed in a chip region in a case of the embodiment of FIG. 2.

FIG. 6 is a plan view, illustrating a semiconductor device, according to another embodiment of the present disclosure.

FIG. 7 is a view, illustrating a method for fabricating the semiconductor device of the embodiment of FIG. 4.

FIG. 8 shows a block diagram illustrating an electronic system employing a memory card including a semiconductor package, according to an embodiment.

FIG. 9 shows a block diagram illustrating another electronic system including a semiconductor package, according to an embodiment.

### DETAILED DESCRIPTION

Hereinafter, various examples of embodiments of the disclosure will be described in detail with reference to the accompanying drawings.

The drawings might not be necessarily to scale and in some instances, proportions of at least some of structures in the drawings may have been exaggerated in order to clearly illustrate certain features of the described examples or implementations. In presenting a specific example in a drawing or description with two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

In the following description of the embodiments, when a parameter is referred to as being “predetermined”, it may be intended to mean that a value of the parameter is determined in advance when the parameter is used in a process or an algorithm. The value of the parameter may be set when the process or the algorithm starts or may be set during a period that the process or the algorithm is executed.

It will be understood that although the terms “first”, “second”, “third” etc. are used herein to describe various elements, these elements should not be limited by these terms. These terms are only used to distinguish one element from another element. Thus, a first element in some embodiments could be termed a second element in other embodiments without departing from the teachings of the present disclosure.

Various embodiments are directed to a semiconductor device capable of facilitating identification of an identification mark located outside a chip region of a semiconductor wafer while making heights of conductive connectors, which are formed in the chip region of the semiconductor wafer, uniform.

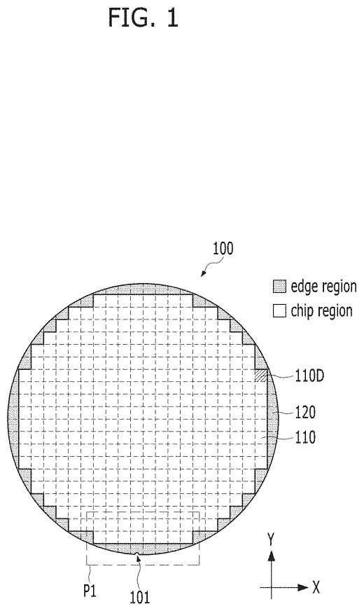

FIG. 1 is a plan view, illustrating a semiconductor wafer, according to an embodiment of the present disclosure. The semiconductor wafer may have a circuit and/or wiring structure formed over a substrate that is formed of a semiconductor material, such as silicon. The circuit and/or wiring structure may be formed by repeatedly performing a film deposition process, a mask and etching process, an ion implantation process, or the like. For convenience of description, one surface of the semiconductor wafer that is shown in the plan view of FIG. 1 will be referred to as a first surface.

Referring to FIG. 1, a semiconductor wafer 100 of the present embodiment may include a chip region 110 and an edge region 120, the edge region 120 being disposed outside of the chip region 110.

The chip region 110 may be a region in that a plurality of semiconductor devices are integrated, and may be formed by a set of a plurality of unit chip regions (refer to regions divided by dotted lines). Each unit chip region may have a rectangular shape in a plan view. For reference, one unit chip region is denoted by a reference numeral 110D. The plurality of unit chip regions may be arranged in a matrix form along X and Y directions.

When a planar area occupied by the chip region 110, of a planar area of the semiconductor wafer 100, increases, it may be advantageous in terms of manufacturing costs. To this end, the unit chip regions may be arranged to maximize the planar area of the chip region 110. Here, since the unit chip region has a rectangular shape, an outline of the chip region 110 may have a shape formed by a combination of a straight line in the X direction and a straight line in the Y direction. On the other hand, the semiconductor wafer 100 may have a circular shape or a shape that is similar to a circular shape. As a result, even if the planar area of the chip region 110 is increased as much as possible, a region remaining outside of the chip region 110 may exist. This region will be referred to as the edge region 120. The edge region 120 may be formed by a set of portions of the unit chip regions.

The edge region 120 may be used in various ways as needed. As an example, an identification mark with identification information may be formed in the edge region 120. The identification information may include characteristics of the semiconductor wafer 100, manufacturing history of the semiconductor wafer 100, or the like. As an example, the identification mark may include a lot number. In addition, as an example, the identification mark may be written in a form of a barcode. Alternatively, as an example, the identification mark may be written in a form of one or more letters, one or more numbers, or a combination thereof, which are serially arranged. The identification mark may be formed on the first surface of the semiconductor wafer 100. In addition, the identification mark may be formed by using etching or laser marking on the first surface of the semiconductor wafer 100, and thus, may be recessed to a predetermined depth from the first surface of the semiconductor wafer 100. However, the present disclosure is not limited thereto, and as long as the identification mark is formed on the first surface of the semiconductor wafer 100 in the edge region 120, the form, the cross-sectional shape, or the like of the identification mark may be variously modified.

When the semiconductor wafer 100 is completely circular, it may be impossible to set a standard during the manufacturing process of the semiconductor wafer 100. Therefore, a notch 101 may be formed on a side surface of the semiconductor wafer 100. The notch 101 may have a V shape or a straight notch (not shown). The semiconductor wafer 100 may be aligned during the manufacturing process based on the notch 101.

Meanwhile, the plurality of unit chip regions may be separated into a plurality of semiconductor chips by dicing along the dotted lines in FIG. 1. Each semiconductor chip may need to be electrically connected to another component (not shown) for packaging. For this reason, conductive connectors for electrically connecting the semiconductor chip and another component may be disposed on the surface of each semiconductor chip. The conductive connectors may be formed on the first surface of the chip region 110 of the semiconductor wafer 100, before dicing. However, whether to form the conductive connectors in the edge region 120 may be considered regardless of the diced semiconductor chip.

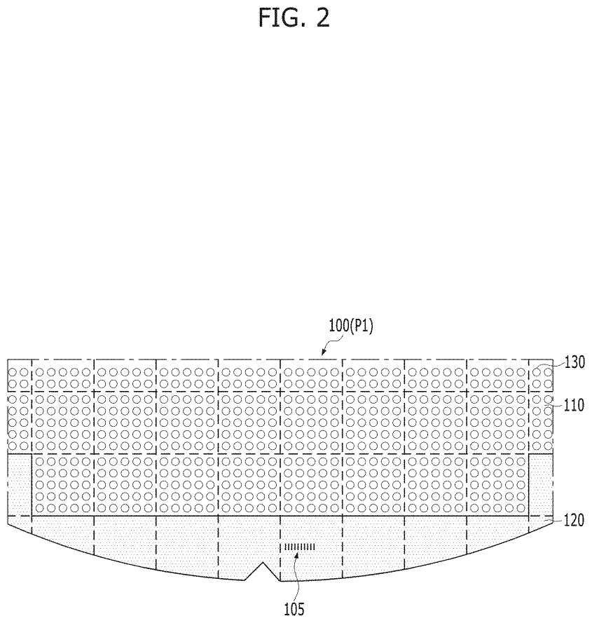

Hereinafter, with reference to FIGS. 2 to 4, it will be described whether to form the conductive connectors in the edge region 120, and how to form the conductive connectors in the edge region 120.

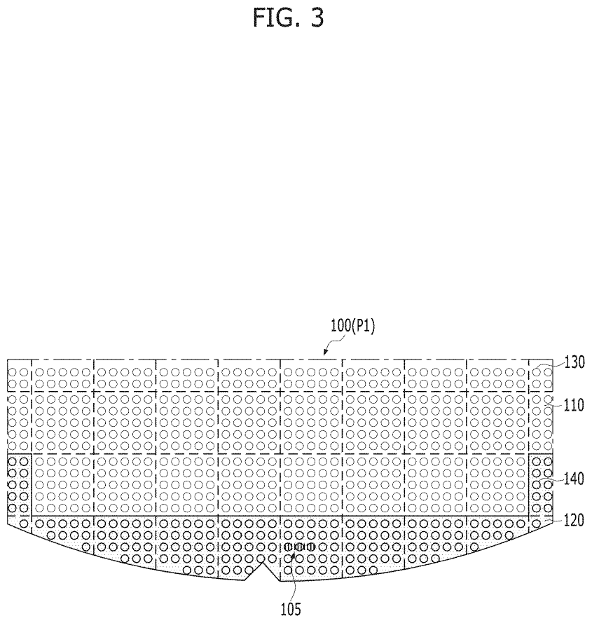

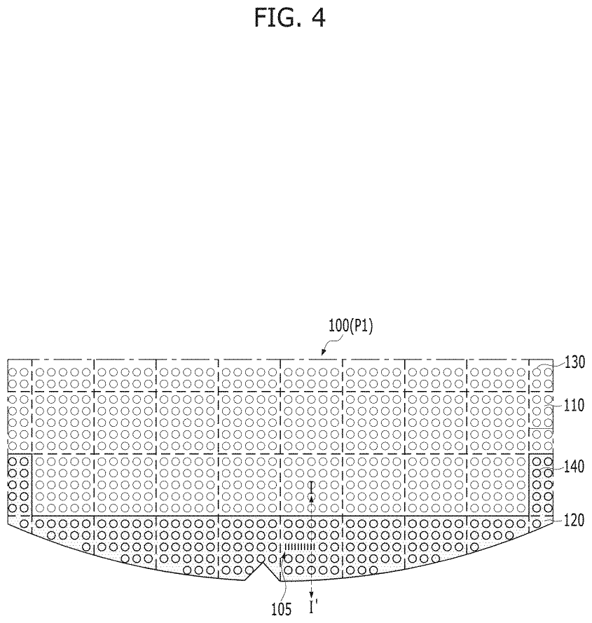

FIGS. 2 to 4 are plan views, illustrating semiconductor devices in accordance with various embodiments of the present disclosure. FIGS. 2 to 4 are enlarged views of a portion P1 of the semiconductor wafer 100 of FIG. 1, showing conductive connectors that are formed on the first surface of the semiconductor wafer 100 together with the semiconductor wafer 100. Specifically, FIG. 2 shows a case in which conductive connectors are formed only in the chip region 110 of the semiconductor wafer 100, FIG. 3 shows a case in which conductive connectors are formed in the chip region 110 and all of the edge region 120 of the semiconductor wafer 100, and FIG. 4 shows a case in which conductive connectors are formed in the chip region 110 and a portion of the edge region 120 of the semiconductor wafer 100.

Referring to FIG. 2, a plurality of conductive connectors 130 may be arranged in the chip region 110 of the semiconductor wafer 100. Although not illustrated, the conductive connectors 130 may be electrically connected to the circuit and/or wiring structure of the chip region 110. The circuit and/or wiring structure that is formed in each of the unit chip regions of the chip region 110 may have the same structure. Accordingly, the conductive connectors 130 in each of the unit chip regions may have the same arrangement. For convenience of description, in the present embodiment, a case in which the plurality of conductive connectors 130 are uniformly formed in the chip region 110 is illustrated. However, the present disclosure is not limited thereto, and the arrangement of the conductive connectors 130 in each of the unit chip regions may be variously modified.

The conductive connector 130 may include a conductive bump. However, the present disclosure is not limited thereto, and the conductive connector 130 may be a 3-dimensional conductor that is implemented in various forms, such as a ball, a pillar, or a combination thereof.

An identification mark 105 may be formed in the edge region 120. In the present embodiment, the identification mark 105 may include a barcode.

However, according to the embodiment of FIG. 2, the following problem may occur.

The conductive connectors 130 may be formed by forming a seed metal layer on the first surface of the semiconductor wafer 100, forming a photoresist on the seed metal layer, the photoresist having openings that expose portions in which the conductive connectors 130 are to be formed, performing an electro-plating process to form conductors that fill the openings, and removing the photoresist. In the present embodiment, because the conductive connectors 130 are formed only in the chip region 110, there is no opening of the photoresist in the edge region 120, and thus, the electro-plating process might not be performed in the edge region 120. However, during the electro-plating process, current flowing through the semiconductor wafer 100 may be concentrated toward the edge region 120 where the electro-plating process is not performed. For this reason, the heights of the conductive connectors 130 that are arranged in a portion of the chip region 110, which is adjacent to the edge region 120, may be higher than the heights of the conductive connectors 130 arranged in the other portion. That is, a problem in which the heights of the conductive connectors 130 are not uniform throughout the chip region 110 may occur.

On the other hand, referring to FIG. 3, not only are the plurality of conductive connectors 130 arranged in the chip region 110 of the semiconductor wafer 100, the plurality of dummy conductive connectors 140 may be arranged in the edge region 120. However, because the edge region 120 is not a portion to be used as a semiconductor chip, the dummy conductive connectors 140 need not be electrically connected to the circuit and/or wiring structure of the edge region 120.

If the dummy conductive connectors 140 are present, the problem of the embodiment of FIG. 2 described above may be solved. Specifically, it is as follows.

The conductive connectors 130 and the dummy conductive connectors 140 may be formed by forming a seed metal layer on the first surface of the semiconductor wafer 100, forming a photoresist with openings exposing portions where the conductive connectors 130 and the dummy conductive connectors 140 are to be formed, on the seed metal layer, performing an electro-plating process to form conductors filling the openings, and removing the photoresist. In the present embodiment, because the conductive connectors 130 are formed in the chip region 110 and the dummy conductive connectors 140 are formed in the edge region 120, the openings of the photoresist may be present in the edge region 120 as well as in the chip region 110, and thus, the electro-plating process may be performed in the edge region 120 as well as in the chip region 110. Therefore, the phenomenon in which the current that flows through the semiconductor wafer 100 during the electro-plating process is concentrated in the edge region 120 may be prevented. As a result, the heights of the conductive connectors 130 in the chip region 110 may be substantially constant.

However, according to the present embodiment, because some of the dummy conductive connectors 140 overlap with the identification mark 105 that were previously formed in the edge region 120, a recognition error with respect to the identification mark 105 may occur. Particularly, as in the present embodiment, when the identification mark 105 is a barcode that is difficult to visually check, this recognition error may be more problematic.

Hereinafter, an embodiment capable of solving both the problem occurring in the embodiment of FIG. 2 and the problem occurring in the embodiment of FIG. 3 will be provided.

Referring to FIG. 4, the plurality of conductive connectors 130 may be arranged in the chip region 110 of the semiconductor wafer 100, and the plurality of dummy conductive connectors 140 may be arranged in the edge region 120.

Here, the dummy conductive connectors 140 may be formed so as not to overlap with the identification mark 105. That is, the dummy conductive connectors 140 may avoid overlapping with the identification mark 105. In the present embodiment, the dummy conductive connectors 140 on the identification mark 105 in the embodiment of FIG. 3 may be removed.

According to the present embodiment, because the openings of a photoresist still exist in the edge region 120 and an electro-plating process is performed accordingly, the current flowing through the semiconductor wafer 100 during the electro-plating process might not be concentrated toward the edge region 120. As a result, the heights of the conductive connectors 130 in the chip region 110 may be substantially constant.

In addition, because the identification mark 105 and the dummy conductive connectors 140 do not overlap, a recognition error of the identification mark 105 may be prevented.

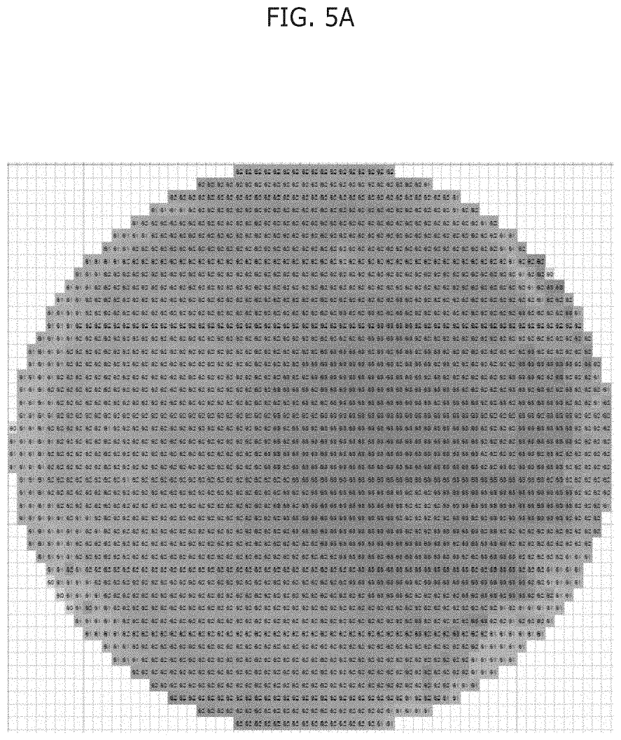

FIG. 5A is a view, illustrating the heights of conductive connectors that are formed in a chip region in a case of the embodiment of FIG. 4, and FIG. 5B is a view, illustrating the heights of conductive connectors that are formed in a chip region in a case of the embodiment of FIG. 2. In FIGS. 5A and 5B, the darkness of the shade may indicate the heights of the conductive connectors formed in a corresponding region. The darker the shade, the higher the heights of the conductive connectors.

Referring to FIG. 5A, it may be seen that the shade is almost similar in the entire chip region. That is, it may be seen that the heights of the conductive connectors that are formed in the entire chip region are almost constant.

On the other hand, referring to FIG. 5B, it may be seen that the shade is dark at a part of the edge of the chip region (see A). That is, it may be seen that the heights of the conductive connectors, which are located near the edge of the chip region, are increased due to the current density.

As a result, according to the embodiment of FIG. 4, the heights of the conductive connectors 130 may be substantially constant throughout the chip region 110.

Meanwhile, even if the dummy conductive connectors 140 on the identification mark 105 are removed as in the embodiment of FIG. 4, the uniformity of the heights of the conductive connectors 130 in the chip region 110 may be secured to the same/similar extent, compared to the case in which the dummy conductive connectors 140 are located on the identification mark 105 as in the embodiment of FIG. 3. This may be shown by referring to [Table 1] below.

TABLE 1

| | | embodiment of FIG. 3 | embodiment of FIG. 4 |
|---|---|---|---|
| electro- | mm² | 1744.45 | 1743.4967 |
| plating | % | 2.469 | 2.468 |
| area | Δ | 0 | −0.0001 |

Referring to [Table 1] above, in the case of the embodiment of FIG. 3, that is, in the case in which the dummy conductive connectors 140 are located in the entire edge region 120 regardless of the identification mark 105, the electro-plating area in the wafer may be about 2.469%. On the other hand, in the case of the embodiment of FIG. 4, that is, in the case in which the dummy conductive connectors 140 are removed on the identification mark 105, the electro-plating area in the wafer may be about 2.468%. That is, only −0.0001% decrease. For reference, the small difference in the electro-plating area in the wafer may mean that the conductive connectors 130 and the dummy conductive connectors 140 are uniformly formed in the embodiments of FIGS. 3 and 4. As a result, in both the embodiments of FIGS. 3 and 4, because the concentration of the current toward the edge region 120 hardly occurs, the heights of the conductive connectors 130 may be uniform.

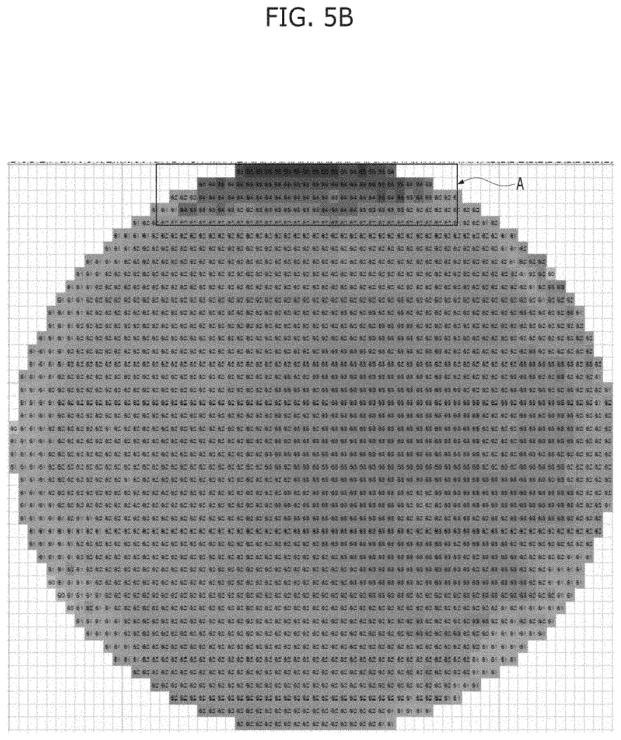

FIG. 6 is a plan view, illustrating a semiconductor device, according to another embodiment of the present disclosure. Like FIGS. 2 to 4, only a portion of a semiconductor wafer is illustrated.

Referring to FIG. 6, a semiconductor wafer 200 of the present embodiment may include a chip region 210 and an edge region 220.

Here, a lot number may be indicated as the identification mark 205 in the edge region 220. For reference, each X of the identification mark 205 may be a letter or a number. This combination of letters and/or numbers may occupy a larger area than a barcode.

Conductive connectors 230 may be disposed on the chip region 210. Dummy conductive connectors 240 may be disposed in the edge region 220, but might not overlap the identification mark 205.

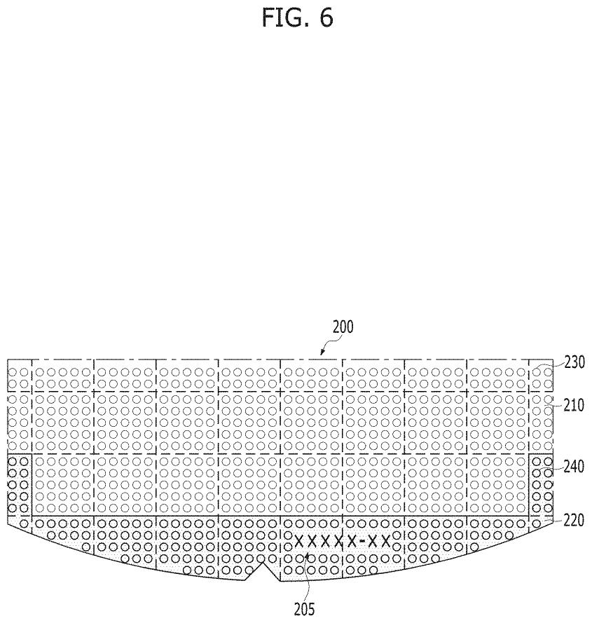

FIG. 7 is a view, illustrating a method for fabricating the semiconductor device of the embodiment of FIG. 4. FIG. 7 is shown based on a cross-section along a line in FIG. 4.

First, referring to step (A) of FIG. 7, the semiconductor wafer 100 with the chip region 110 and the edge region 120 may be provided. In the chip region 110, a chip pad PD to be connected to a conductive connector 130, described later, may be formed on a first surface 102 of the semiconductor wafer 100. Also, in the edge region 120, the identification mark 105 may be formed on the first surface 102 of the semiconductor wafer 100. For convenience of description, the identification mark 105 is shown in a square shape. However, the cross-sectional shape of the identification mark 105 may be variously modified.

Subsequently, a seed layer SL that covers the first surface 102 of the semiconductor wafer 100 may be formed. The seed layer SL may include metal, metal nitride, or a combination thereof.

Subsequently, referring to step (B), a photoresist pattern PR may be formed over the seed layer SL. The photoresist pattern PR may have a plurality of openings in the chip region 110 and the edge region 120. These openings may provide spaces in which conductive connectors in the chip region 110 and dummy conductive connectors in the edge region 120 are to be formed. The opening of the photoresist pattern PR in the chip region 110 may overlap with the chip pad PD. On the other hand, the photoresist pattern PR in the edge region 120 may cover the identification mark 105.

Subsequently, referring to step (C), an initial bump 1300 and an initial dummy bump 1400 filling the openings of the photoresist pattern PR may be formed. In the present embodiment, the initial bump 1300 may include a stacked structure of an initial metal post 1320 and an initial metal bonding layer 1340. The initial metal post 1320 may have a pillar shape and may be formed through an electro-plating process to include the same metal as the seed layer SL. The initial metal post 1320 may be a portion that is electrically connected to the chip pad PD and may include a metal with high electrical conductivity, such as copper (Cu). The initial metal bonding layer 1340 may be a component that connects the semiconductor chip, formed from the semiconductor wafer 100, to an external device and may be a pillar-shaped solder layer. The initial dummy bump 1400 may be formed together with the initial bump 1300 through the same process as the initial bump 1300. Accordingly, the initial dummy bump 1400 may also include a stacked structure of an initial metal post 1420 and an initial metal bonding layer 1440. Because the photoresist pattern PR covers the identification mark 105 in the edge region 120, the initial dummy bump 1400 may be formed at a position that does not overlap with the identification mark 105. For example, the initial dummy bump 1400 and the identification mark 105 may be spaced apart from each other in a lateral direction. That is, the initial dummy bump 1400 might not overlap with the identification mark 105 in a vertical direction.

Subsequently, referring to step (D), the photoresist pattern PR may be removed. The photoresist pattern PR may be removed by a strip process or the like.

Subsequently, referring to step (E), by performing a wet etching and reflow process, a bump 1300′ and a dummy bump 1400′ with a desired shape may be formed while removing a portion of the seed layer SL. That is, in the wet etching and reflow process, the initial bump 1300 and the initial dummy bump 1400 may be trimmed to form the bump 1300′ and the dummy bump 1400′ while the seed layer SL is positioned only under the bump 1300′ and the dummy bump 1400′. The seed layer SL may be removed on the identification mark 105. The bump 1300′ may include a stacked structure of a metal post 1320′ and a metal bonding layer 1340′. The metal post 1320′ may have a smaller width than the initial metal post 1320, but may maintain a pillar shape. On the other hand, the metal bonding layer 1340′ may be deformed to have a hemispherical shape or a similar shape through the reflow process. The dummy bump 1400′ may include a stacked structure of a metal post 1420′ and a metal bonding layer 1400′, similar to the bump 1300′. The dummy bump 1400′ might also not overlap with the identification mark 105. For example, the dummy bump 1400′ may also be spaced apart from the identification mark 105 in the lateral direction. The bump 1300′ may correspond to the conductive connector (see 130 in FIG. 4) of the above-described embodiment, and the dummy bump 1400′ may correspond to the dummy conductive connector (see 140 in FIG. 4) of the above-described embodiment.

The bump 1300′ may be electrically connected to the chip pad PD of the chip region 110 while contacting the seed layer SL. On the other hand, the dummy bump 1400′ may contact the seed layer SL, but might not be electrically connected to the chip pad PD of the chip region 110. Furthermore, even when a chip pad (not shown) is further present in the edge region 120, the dummy bump 1400′ might not be electrically connected to this chip pad.

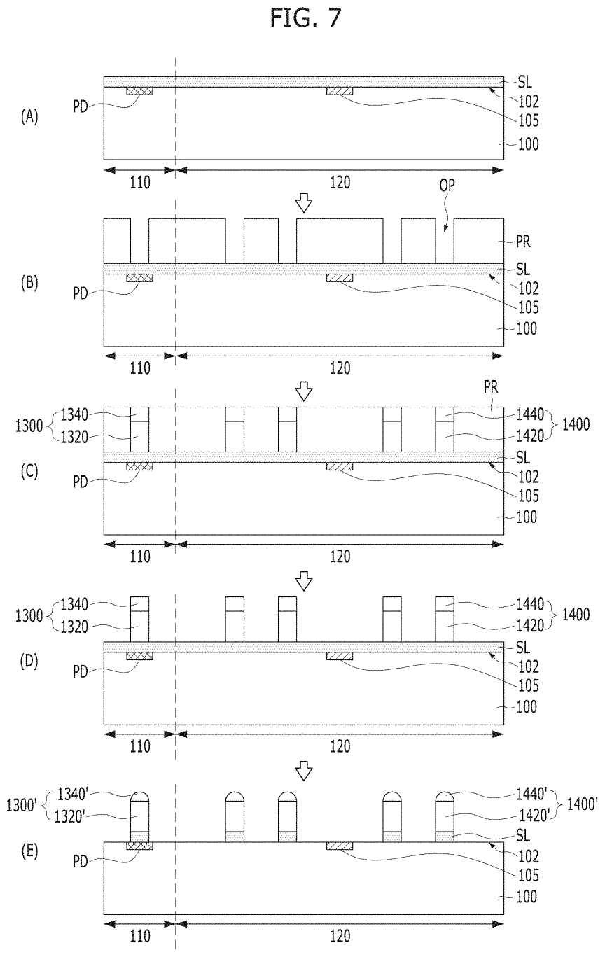

FIG. 8 shows a block diagram illustrating an electronic system including a memory card 7800 employing at least one of the semiconductor packages according to the embodiments. The memory card 7800 includes a memory 7810, such as a nonvolatile memory device, and a memory controller 7820. The memory 7810 and the memory controller 7820 may store data or read out the stored data. At least one of the memory 7810 and the memory controller 7820 may include at least one of the semiconductor packages according to described embodiments.

The memory 7810 may include a nonvolatile memory device to which the technology of the embodiments of the present disclosure is applied. The memory controller 7820 may control the memory 7810 such that stored data is read out or data is stored in response to a read/write request from a host 7830.

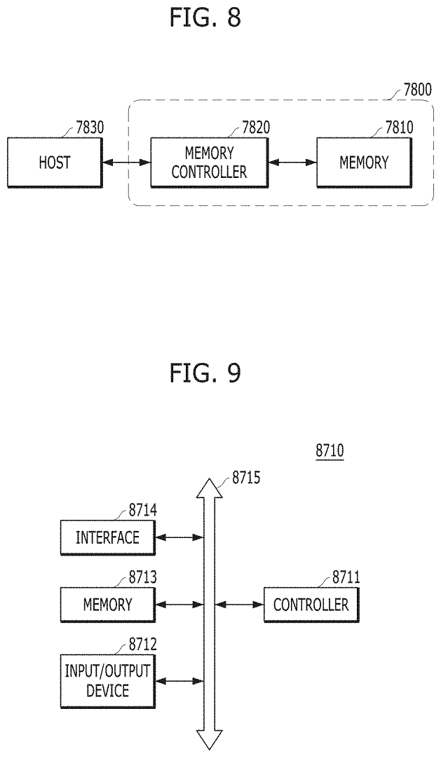

FIG. 9 shows a block diagram illustrating an electronic system 8710 including at least one of the semiconductor packages according to described embodiments. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include one or more of the semiconductor packages according to the embodiments of the present disclosure. The input/output device 8712 may include at least one selected among a keypad, a keyboard, a display device, a touchscreen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system.

If the electronic system 8710 represents equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution), or Wibro (wireless broadband Internet).

Although various embodiments have been described for illustrative purposes, it will be apparent to those skilled in the art that various changes and modifications may be made without departing from the spirit and scope of the invention as defined in the following claims.

What is claimed is:

1. A semiconductor device comprising:
a semiconductor wafer with a chip region and an edge region and with an identification mark formed on one surface of the semiconductor wafer in the edge region;
conductive connectors formed on the one surface of the semiconductor wafer in the chip region; and
dummy conductive connectors formed on the one surface of the semiconductor wafer in the edge region,
wherein the dummy conductive connectors do not overlap with the identification mark.

2. The semiconductor device according to claim 1, wherein the identification mark includes a barcode.

3. The semiconductor device according to claim 1, wherein the identification mark includes a letter, a number, or a combination thereof.

4. The semiconductor device according to claim 1, wherein the conductive connectors and the dummy conductive connectors have the same shape as each other.

5. The semiconductor device according to claim 1, wherein the conductive connectors and the dummy conductive connectors include conductive bumps.

6. The semiconductor device according to claim 1, wherein the semiconductor wafer includes a wiring structure,
the conductive connectors are electrically connected to the wiring structure, and
the dummy conductive connectors are electrically separated from the wiring structure.

7. The semiconductor device according to claim 1, wherein the identification mark and the dummy conductive connectors are spaced apart from each other in a lateral direction.

8. The semiconductor device according to claim 1, further comprising:
a seed layer interposed between the one surface of the semiconductor wafer and each of the conductive connectors, and interposed between the one surface of the semiconductor wafer and each of the dummy conductive connectors,
wherein the seed layer does not overlap with the identification mark in a vertical direction.

9. The semiconductor device according to claim 1, wherein the identification mark is recessed to a predetermined depth from the one surface of the semiconductor wafer, and
wherein the conductive connectors and the dummy conductive connectors protrude from the one surface of the semiconductor wafer.

10. The semiconductor device according to claim 1, wherein the semiconductor wafer includes chip pads in the chip region,
wherein the conductive connectors are electrically connected to the chip pads, and
wherein the dummy conductive connectors are not electrically connected to the chip pads.

11. A semiconductor device comprising:
a semiconductor wafer with a chip region and an edge region and with an identification mark formed on one surface of the semiconductor wafer in the edge region;
conductive connectors formed on the one surface of the semiconductor wafer in the chip region; and
dummy conductive connectors formed on the one surface of the semiconductor wafer in the edge region,
wherein the dummy conductive connectors avoid overlapping with the identification mark.
